(19) United States
(12) Patent Application Publication
(10) Pub. No.: US 2013/0139383 A1
(43) Pub. Date: Jun. 6, 2013

(54) Printed Circuit Board and Method Of Manufacturing The Same

(71) Applicant: SAMSUNG ELECTRO-MECHANICS CO., LTD., Gyunggi-do (KR)

(72) Inventors: Kye Won Choi, Gyeongsangnam-do (KR); Da Hee Joung, Gyeongsangnam-do (KR); Cheol Ho Heo, Busan (KR); Myung Gun Chong, Gyeongsangnam-do (KR); Sung Jun Lee, Busan (KR)

(73) Assignee: SAMSUNG ELECTRO-MECHANICS CO., LTD., Suwon (KR)

(21) Appl. No.: 13/752,258

(22) Filed: Jan. 28, 2013

Related U.S. Application Data
(62) Division of application No. 12/911,627, filed on Oct. 25, 2010, now abandoned.

(30) Foreign Application Priority Data
Apr. 30, 2010 (KR) 10-2010-0048094

(51) Int. Cl. H05K 3/42

(52) U.S. Cl. CPC H05K 3/429
USPC 29/852

(57) ABSTRACT

Disclosed herein is a printed circuit board, including: a substrate including a first circuit layer formed on one side thereof and a second circuit layer formed on the other side thereof; and a strike-type through body externally inserted in the substrate and electrically connecting the first circuit layer and the second circuit layer. The printed circuit board is advantageous in that, since a strike-type through body is externally inserted in a substrate, conventional complicated processes, such as hole forming, deburring, desmearing, electroless copper plating and electrolytic copper plating, can be omitted, thus simplifying a process of manufacturing a printed circuit board and reducing the manufacturing cost thereof.

### CROSS REFERENCE TO RELATED APPLICATION

This application is a Divisional application of U.S. patent application Ser. No. 12/911,627 filed Oct. 25, 2010, entitled “Printed Circuit Board and Method of Manufacturing the Same” which claims the benefit of Korean Patent Application No. 10-2010-0040894, filed Apr. 30, 2010, entitled “A printed circuit board and a method of manufacturing the same”, both of which are hereby incorporated by reference in their entirety into this application.

### BACKGROUND OF THE INVENTION

1. Technical Field

The present invention relates to a printed circuit board and a method for manufacturing the same.

2. Description of the Related Art

Recently, in order to keep up with the densification of semiconductor chips and the increase of signal transfer speed, a technology of directly mounting a semiconductor chip in a substrate has been increasingly required. Therefore, it is also required to develop a high-density and high-reliability substrate which can cope with the densification of semiconductor chips.

The required specifications of a high-density and high-reliability substrate are closely related to the specifications of a semiconductor chip, and have many problems to be solved, such as the miniaturization of circuits, excellent electrical properties, high-speed signal transmission, high reliability, high functionality and the like. In order to solve these problems, technologies for forming a through hole in a printed circuit board are required.

FIGS. 1 to 4 are sectional views sequentially showing a conventional method of forming a through hole, FIG. 5 is a flowchart showing desmearing work, and FIG. 6 is a flowchart showing electroless copper plating work. Hereinafter, the conventional method of forming a through hole will be described with reference to FIGS. 1 to 6.

As shown in FIGS. 1 to 4, the conventional method of forming a through hole includes the steps of: (A) providing a copper clad laminate 1; (B) forming a hole 2 in the copper clad laminate 1 and then deburring and desmearing the copper clad laminate 1; (C) electroless-copper-plating the copper clad laminate 1; and (D) electrolytic-copper-plating the copper clad laminate.

First, as shown in FIG. 1, a copper clad laminate (1) including an insulation layer whose both sides are coated with copper foil is provided.

Subsequently, as shown in FIG. 2, a hole 2 is formed in the copper clad laminate 1, and then the copper clad laminate 1 is deburred and desmeared.

The hole 2 may be formed using a CO₂ laser, a UV YAG laser or a drill. Among these, a method of forming the hole 2 using a CO₂ laser and a method of forming the hole 2 using a drill are generally used. These methods are advantageous in that the hole 2 can be rapidly formed and high productivity can be realized, but are problematic in that it is difficult to precisely form a micro through hole, and a relative large amount of smear remains on the inner wall of the copper clad laminate 1, thus decreasing the connection reliability of a through hole. Meanwhile, a method of forming the hole 2 using a UV YAG laser is advantageous compared to the above methods because a micro through hole can be formed using high power and a small amount of smear remains on the inner wall of the copper clad laminate, but is problematic in that hole-forming speed is slow, and productivity is decreased, and thus it is not suitable for the mass production of a printed circuit board. In addition, the hole 2 may be formed using an excimer laser, a nanosecond laser, a femtosecond laser or the like. However, methods of forming the hole 2 using an excimer laser, a nanosecond laser, a femtosecond laser or the like are also problematic in that the production cost of a printed circuit board is high, and thus it is difficult to produce a printed circuit board in large amounts.

As described above, the conventional method of forming a through hole is problematic in that it is accompanied by high production costs, productivity is increased, and the reliability of the connection of a through hole is decreased due to smears occurring at the time of forming the hole 2, thus deteriorating the quality of a printed circuit board.

Further, after the formation of the hole 2, in order to remove burrs and smears, deburring work and desmearing work must be conducted. Here, the desmearing work includes very complicated processes. Referring to FIG. 5, the desmearing work is conducted by the processes of swelling (relaxing and expanding smears)→water washing→desmearing (chemically removing smears)→primary neutralization→water washing→secondary neutralization→water washing. As such, since complicated processes must be undergone in order to conduct the desmearing work, there is a problem in that a process of manufacturing a printed circuit board becomes complicated, thus increasing the manufacturing cost of the printed circuit board.

Subsequently, as shown in FIG. 3, the copper clad laminate 1 is electroless-copper-plated to form an electroless plating layer 3. Here, the electroless copper plating work also includes very complicated processes. Referring to FIG. 6, the electroless copper plating work is conducted by the processes of pre-catalyst treatment→catalyst treatment (coating the inner wall of the copper clad laminate with catalyst particles)→activating (ionizing catalyst)→electroless copper plating→antioxidizing (coating an antioxidant film). As such, since complicated processes must be undergone in order to conduct the electroless copper plating work, there is a problem in that a process of manufacturing a printed circuit board becomes complicated, thus increasing the manufacturing cost of the printed circuit board.

Subsequently, as shown in FIG. 4, the copper clad laminate 1 is electrolytic-copper-plated to form an electrolytic plating layer 4. Here, since the copper clad laminate 1 acquired conductivity through the previous electroless copper plating work, the electrolytic copper plating of the copper clad laminate 1 is conducted using electrolysis, thereby completing the formation of a through hole.

As described above, the conventional method of forming a through hole is problematic in that a process of manufacturing a printed circuit board become complicated and thus the manufacturing cost of the printed circuit board is increased because the reliability of a through hole is decreased due to the occurrence of smears and because it includes complicated processes of hole forming→deburring→desmearing→electroless copper plating→electrolytic copper plating.

### SUMMARY OF THE INVENTION

Accordingly, the present invention has been devised to solve the above-mentioned problems, and the present invention provides a printed circuit board which can be manufactured by a simple process and can secure the reliability of a strike-type through body because a strike-type through body is externally inserted into a substrate to electrically connect circuit layers formed on both sides of the substrate, and a method of manufacturing the same.

An aspect of the present invention provides a printed circuit board, including: a substrate including a first circuit layer formed on one side thereof and a second circuit layer formed on the other side thereof; and a strike-type through body externally inserted in the substrate and electrically connecting the first circuit layer and the second circuit layer.

Here, the strike-type through body may be made of a conductive material.

Further, the strike-type through body may be made of copper.

Further, one end of the strike-type through body may be curved.

Further, the strike-type through body may be screwed into the substrate.

Further, the substrate may be an insulation layer.

Further, the substrate may be a copper clad laminate.

Another aspect of the present invention provides a method of manufacturing a printed circuit board, including: providing a substrate; externally inserting a strike-type through body into the substrate to allow the strike-type through body to penetrate the substrate; and forming a first circuit layer on one side of the substrate and forming a second circuit layer on the other side of the substrate to allow the first circuit layer and the second circuit layer to be electrically connected with each other through the strike-type through body.

Here, in the inserting of the strike-type through body, the strike-type through body may be inserted into the substrate in a gas punching manner.

Further, in the inserting of the strike-type through body, the strike-type through body may be made of a conductive material.

Further, in the inserting of the strike-type through body, the strike-type through body may be made of copper.

Further, in the inserting of the strike-type through body, one end of the strike-type through body may be curved.

Further, in the inserting of the strike-type through body, the strike-type through body may be screwed into the substrate.

Further, the strike-type through body may be inserted into the substrate by rotating the strike-type through body in a thickness direction of the substrate.

Further, the substrate may be an insulation layer.

Further, the substrate may be a copper clad laminate.

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

### BRIEF DESCRIPTION OF THE DRAWINGS

The above and other objects, features and advantages of the present invention will be more clearly understood from the following detailed description taken in conjunction with the accompanying drawings, in which:

FIGS. 1 to 4 are sectional views sequentially showing a conventional method of forming a strike-type through body;

FIG. 5 is a flowchart showing desmearing work;

FIG. 6 is a flowchart showing electroless copper plating work;

FIGS. 7 to 10 are sectional views showing a printed circuit board according to an embodiment of the present invention; and

FIGS. 11 to 16 are sectional views sequentially showing a method of manufacturing a printed circuit board according to an embodiment of the present invention.

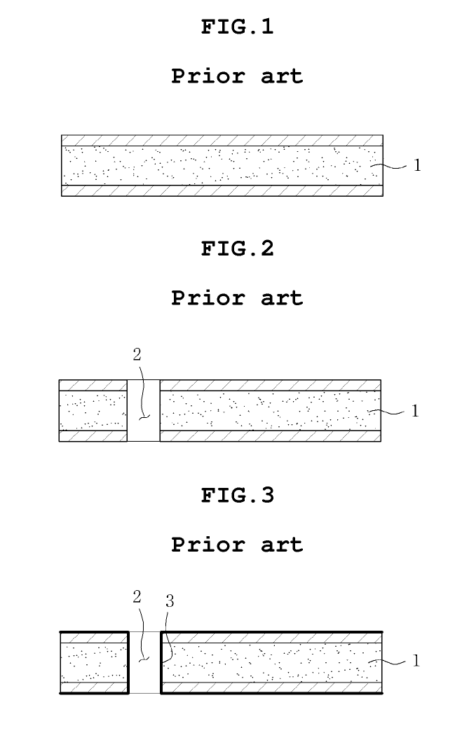

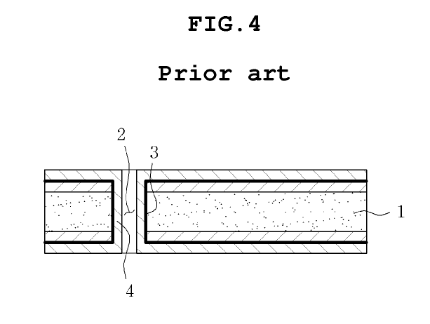

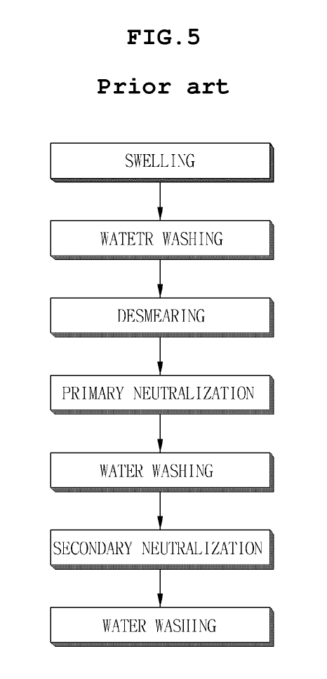

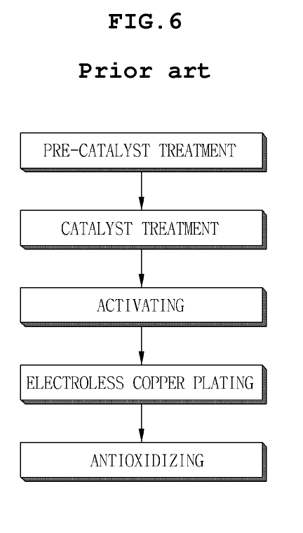

### DESCRIPTION OF THE PREFERRED EMBODIMENTS

The objects, features and advantages of the present invention will be more clearly understood from the following detailed description and preferred embodiments taken in conjunction with the accompanying drawings. Throughout the accompanying drawings, the same reference numerals are used to designate the same or similar components, and redundant descriptions thereof are omitted. Further, in the following description, the terms “first,” “second” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

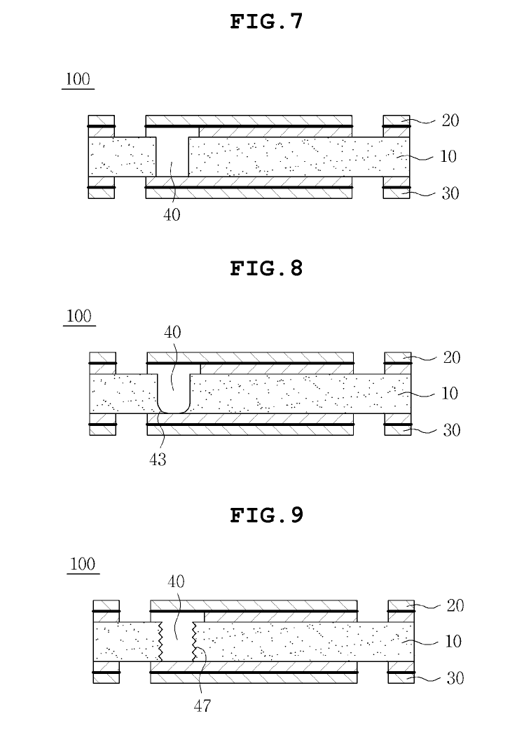

FIGS. 7 to 10 are sectional views showing printed circuit boards according to preferred embodiments of the present invention.

As shown in FIGS. 7 to 10, a printed circuit board 100 according to an embodiment of the present invention includes: a substrate 10 including a first circuit layer 20 formed on one side thereof and a second circuit layer 30 formed on the other side thereof; and a strike-type through body 40 externally inserted in the substrate 10 and electrically connecting the first circuit layer 20 and the second circuit layer 30

The substrate 10, which includes the first circuit layer 20 and the second circuit layer 30 formed on both sides thereof, may be a copper clad laminate as shown in the drawings. However, the substrate 10 is not limited thereto, and may be an insulation layer formed of an epoxy resin such as FR-4 or bismaleimide triazine (BT), prepreg, ajinomoto build up film (ABF) or the like.

The strike-type through body 40, which serves to electrically connect the first circuit layer 120 and the second circuit layer 130, is externally inserted in the substrate 10 in a gas punching manner to penetrate the substrate 10. Since the strike-type through body 40 is externally inserted in the substrate 10, the above conventional complicated processes, such as hole forming, deburring, desmearing, electroless copper plating and electrolytic copper plating, can be omitted, thus simplifying a process of manufacturing a printed circuit board. Further, since smears do not occur, the reliability of a strike-type through body can be ensured.

Meanwhile, the strike-type through body 40 must be made of a conductive material in order to electrically connect the first circuit layer 20 and the second circuit layer 30. More preferably, the strike-type through body 40 may be made of copper having high electroconductivity and a relatively low price.

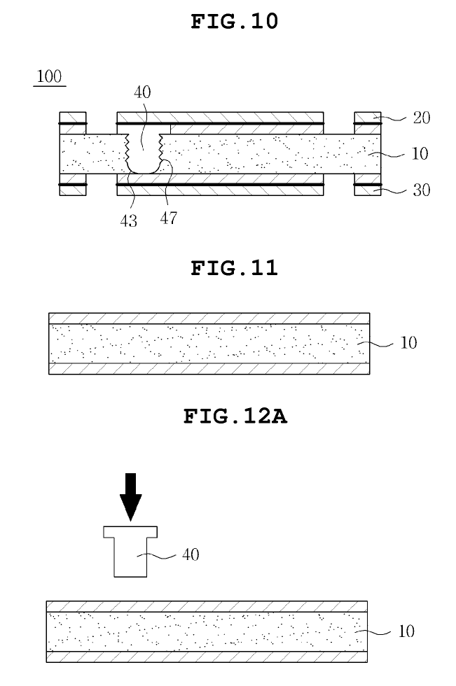

Meanwhile, as shown in FIGS. 8 to 10, the strike-type through body 40 may have various shapes. For example, one end of the strike-type through body 40 is curved, thus enabling the strike-type through body 40 to be more easily inserted in the substrate 10 (refer to FIG. 8). Further, the circumference of the strike-type through body 40 is threaded, thus enabling the strike-type through body 40 to be more strongly coupled with the substrate 10 (refer to FIG. 9). In this case, the strike-type through body 40 can be inserted in the substrate 10 by rotating the strike-type through body 40 in the thickness direction of the substrate. In addition, one end of the strike-type through body 40 is curved and simultaneously the circumference of the strike-type through body 40 is threaded, thus maximizing the above effects (refer to FIG. 10).

FIGS. 11 to 16 are sectional views sequentially showing a method of manufacturing a printed circuit board according to an embodiment of the present invention.

As shown in FIGS. 11 to 16, a method of manufacturing a printed circuit board according to an embodiment of the present invention includes the steps of: (A) providing a substrate 10; (B) externally inserting a strike-type through body 40 into the substrate 10 to allow the strike-type through body 40 to penetrate the substrate 10; (C) forming a first circuit layer 20 on one side of the substrate and forming a second circuit layer 30 on the other side of the substrate 10 to allow the first circuit layer 20 and the second circuit layer 30 to be electrically connected with each other through the strike-type through body 40.

First, as shown in FIG. 11, a substrate 10, into which a strike-type through body 40 is to be inserted, is provided. Here, the substrate 10 may be used without limitation as long as it is an insulation layer generally used in printed circuit boards. For example, a copper clad laminate may be used as the substrate 10.

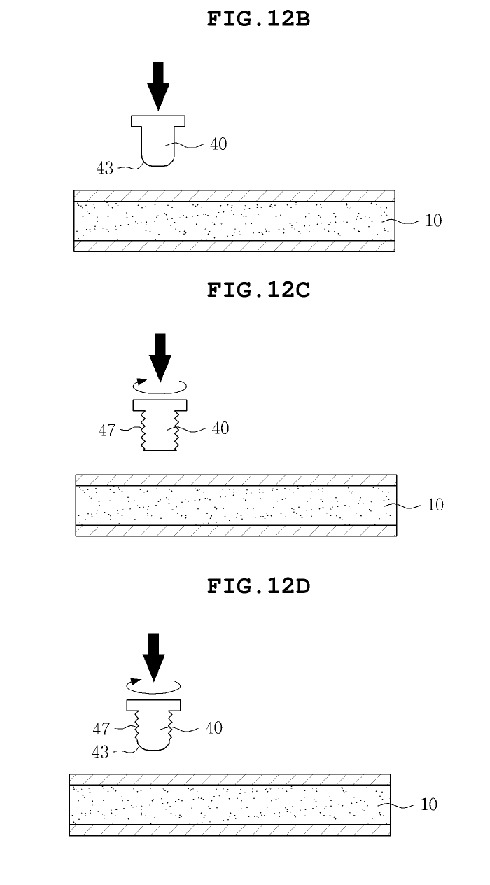

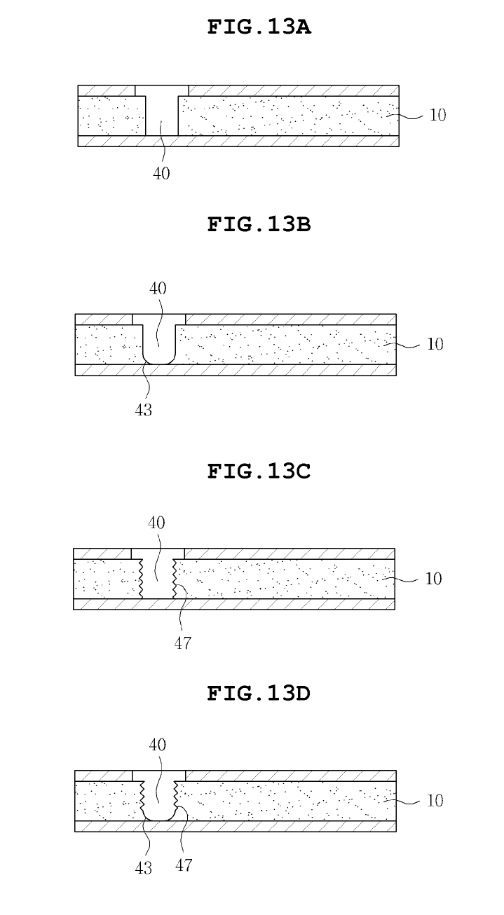

Subsequently, as shown in FIGS. 12 to 13, a strike-type through body 40 is inserted into the substrate 10. The method of inserting the strike-type through body 40 into the substrate 10 is not particularly limited, but the strike-type through body 40 may be inserted into the substrate in a gas punching manner in consideration of precise position control and processing speed. Since the strike-type through body 40 is externally formed and then inserted into the substrate 10, a process of manufacturing a printed circuit board can be simplified compared to the above conventional method of forming a through hole.

Further, the strike-type through body 40 usually has a cylindrical shape (refer to FIGS. 12A and 13A) and may have various other shapes as well. For example, one end of the strike-type through body 40 may be curved (refer to FIGS. 12B and 13B), the circumference of the strike-type through body 40 may be threaded (refer to FIGS. 12C and 13C), or one end of the strike-type through body 40 is curved and simultaneously the circumference of the strike-type through body 40 is threaded (refer to FIGS. 12D and 13D). Here, when the circumference of the strike-type through body 40 is threaded (refer to FIGS. 12C and 13C), the strike-type through body 40 can be more easily inserted into the substrate 10 by rotating the strike-type through body 40 in the thickness direction of the substrate 10, and, after the strike-type through body 40 is inserted into the substrate, the strike-type through body 40 can be more strongly coupled with the substrate 10 (refer to FIGS. 13C and 13D).

Meanwhile, the strike-type through body 40 must be made of a conductive material because it serves to electrically connect a first circuit layer 20 and a second circuit layer 30, which are to be formed in subsequent processes. More preferably, the strike-type through body 40 may be made of copper having high electroconductivity and relatively low price.

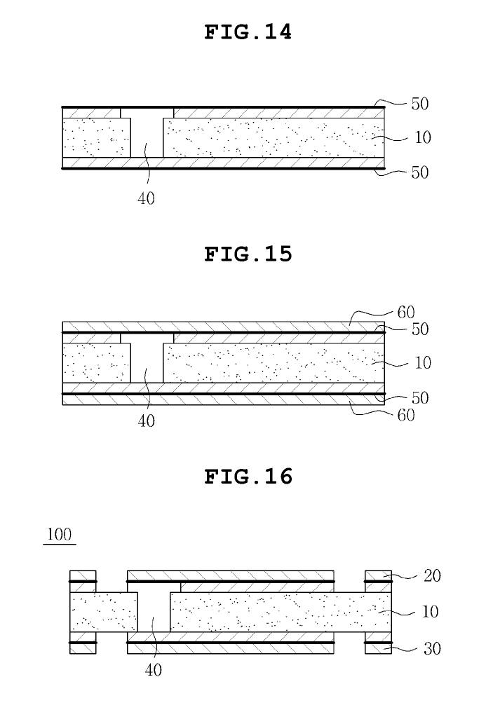

Subsequently, as shown in FIGS. 14 to 16, a first circuit layer 20 and a second circuit layer 30 are formed on both sides of the substrate 10, respectively, to allow the first circuit layer 20 and the second circuit layer 30 to be electrically connected with each other through the strike-type through body 40. Here, the process of forming the first circuit layer 20 and the second circuit layer 30 is described in more detail as follows. First, electroless plating layers 50 are formed on both sides of the substrate 10 through an electroless plating process (refer to FIG. 14). Subsequently, electrolytic plating layers 60 are formed on the electroless plating layers 50 by performing an electrolytic plating process in which the electroless plating layers 50 are used as seed layers (refer to FIG. 15), and then the electrolytic plating layers 60 are selectively etched to form the first circuit layer 20 and the second circuit layer 30 (refer to FIG.

16). However, the first circuit layer 20 and the second circuit layer 30 may be formed using other methods in addition to the above method.

Meanwhile, this process of forming the first circuit layer 20 and the second circuit layer 30 is conducted in the same manner without regard to the shape of the strike-type through body 40. Therefore, since the process of forming the first circuit layer 20 and the second circuit layer 30 using the strike-type through body 40 having a curved portion 43 or a threaded portion 47 is conducted in the same manner as the process of forming the first circuit layer 20 and the second circuit layer 30 using the cylindrical strike-type through body 40, the drawings related thereto are not shown.

As described above, according to the present invention, since a strike-type through body is externally inserted in a substrate, the above conventional complicated processes, such as hole forming, deburring, desmearing, electroless copper plating and electrolytic copper plating, can be omitted, thus simplifying a process of manufacturing a printed circuit board and reducing the manufacturing cost thereof.

Further, according to the present invention, since a strike-type through body is directly inserted into a substrate, smears do not occur, thus ensuring the reliability of a strike-type through body.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Simple modifications, additions and substitutions of the present invention belong to the scope of the present invention, and the specific scope of the present invention will be clearly defined by the appended claims.

What is claimed is:

1. A method of manufacturing a printed circuit board, comprising:
providing a substrate;
externally inserting a strike-type through body into the substrate to allow the strike-type through body to penetrate the substrate; and
forming a first circuit layer on one side of the substrate and forming a second circuit layer on the other side of the substrate to allow the first circuit layer and the second circuit layer to be electrically connected with each other through the strike-type through body.

2. The method according to claim 1, wherein, in the inserting of the strike-type through body, the strike-type through body is inserted into the substrate in a gas punching manner.

3. The method according to claim 1, wherein, in the inserting of the strike-type through body, the strike-type through body is made of a conductive material.

4. The method according to claim 1, wherein, in the inserting of the strike-type through body, the strike-type through body is made of copper.

5. The method according to claim 1, wherein, in the inserting of the strike-type through body, one end of the strike-type through body is curved.

6. The method according to claim 1, wherein, in the inserting of the strike-type through body, the strike-type through body is screwed into the substrate.

7. The method according to claim 6, wherein, in the inserting of the strike-type through body, the strike-type through body is inserted into the substrate by rotating the strike-type through body in a thickness direction of the substrate.

8. The method according to claim 1, wherein, in the providing of the substrate, the substrate is an insulation layer.

9. The method according to claim 1, wherein, in the providing of the substrate, the substrate is a copper clad laminate.
